(19) United States
(12) Patent Application Publication
(10) Pub. No.: US 2006/0187647 A1
(43) Pub. Date: Aug. 24, 2006

(54) Test kit semiconductor package and method of testing semiconductor package using the same

(76) Inventors: Hyun-Guen Iy, Asan-si (KR); Jeong-Ho Bang, Yongin-si (KR); Hyun-Seop Shim, Incheon Metropolitan City (KR); Jae-il Lee, Yongin-si (KR); Kum-Jin Yun, Cheonan-si (KR)

Correspondence Address: HARNESS, DICKEY & PIERCE, P.L.C., P.O. BOX 8910, RESTON, VA, 20195, US

(21) Appl. No.: 11/347,569

(22) Filed: Feb. 6, 2006

(30) Foreign Application Priority Data
Feb. 4, 2005 (KR) 10-2005-0010731

(51) Int. Cl. H05K 7/20

(52) U.S. Cl. 361/719

(57) ABSTRACT

A test kit for a semiconductor package and a method of testing a semiconductor package using the same are provided. The test kit may include a pick-and-place tool for loading/unloading a semiconductor package, a head assembly for guiding a semiconductor package released from the pick-and-place tool, and a socket for receiving the semiconductor package from the pick-and-place tool. The method may include performing pre-alignment by inserting one or more slide posts of an alignment tool into a socket, releasing a semiconductor package through a package guider, and attaching the semiconductor package onto a socket.

### PRIORITY STATEMENT

This application claims the benefit of Korean Patent Application No. 10-2005-0010731, filed on Feb. 4, 2005, in the Korean Intellectual Property Office, the disclosure of which is incorporated herein in its entirety by reference.

### BACKGROUND OF THE INVENTION

1. Field of the Invention

Example embodiments of the present invention relate to a test kit for a semiconductor package and method of testing a semiconductor package using the same, and more particularly, to a head assembly and socket which are used to test a semiconductor package and a testing method using the head assembly and socket.

2. Description of the Related Art

As a semiconductor package decreases in size, e.g., gets thinner and/or smaller, the semiconductor package may be changed from a quad flat package using lead for an external connection terminal to a ball grid array (BGA) package using a solder ball and/or a land grid array (LGA) package using a solder land.

Semiconductor devices may be tested several times during fabrication to determine functionality and/or acceptability. Testing of semiconductor devices may be performed using a tester that may include a computer and/or various measuring tools. Electrical tests may include, but are not limited to, an electrical die sorting (EDS) test performed on a wafer, a final test performed on an assembled semiconductor package, a reliability test performed on semiconductor chips on a wafer and/or an assembled semiconductor package, etc.

A final test may include a room temperature electrical final test, a cold temperature electrical final test performed at a temperature lower than room temperature, and a hot temperature electrical final test performed at a temperature higher than room temperature. There are many kinds of reliability tests. For example, a burn-in test may be performed using a socket. In a burn-in test, semiconductor devices may be exposed to severe conditions such as high temperature and high voltage, low temperature and high voltage, etc., so that semiconductor devices which may have a tendency for failure may be initially screened out.

Electrical tests, which may use one or more testers testing semiconductor devices, may be divided into serial tests and parallel tests according to a testing scheme used by the tester. In a serial test, semiconductor packages may be tested one by one. In a parallel test, many semiconductor chips and/or semiconductor packages may be substantially simultaneously tested.

During an example, parallel, burn-in test, 32 to 256 sockets may be included in a single interface board so that a plurality of semiconductor chips and/or semiconductor packages may be tested substantially simultaneously and collectively. The interface board may electrically connect semiconductor devices to a tester.

FIG. 1 is a sectional view of a conventional burn-in board mounted with a socket. FIG. 2 is a top view of a conventional socket. FIG. 3 is a side view of a conventional socket.

Referring to FIGS. 1 through 3, a socket 200 may be mounted on a burn-in board by, for example, installing an auxiliary board 10 over an interface board 20 using supporters 12 and then installing a socket 200 on the auxiliary board 10. The socket 200 may include a socket body 214, a cover 202, a socket contact board 208, socket pins 210, and a latch 204 used to attach a semiconductor package to the socket contact board 208.

For example, a cover 202 of the socket 200 may push down a latch 204 so that a semiconductor package is loaded into the socket 200 as shown in FIG. 4 and may release the latch 204 so that the loaded semiconductor package is attached to a socket contact board 208. In addition, the cover 202 may push down a slide driver (not shown) positioned therebelow to open and/or close socket pins 210 on the socket contact board 208 so that the solder balls of a semiconductor package may be connected to the socket pins 210.

In monitoring burn-in test (MBT) equipment, several tens of burn-in boards, each mounted with the socket 200 may be inserted into separate slots, respectively, for example, in a chamber referred to as a rack for a burn-in test. Spacing between vertically adjacent burn-in boards may be narrow. As a result, a support base 22 of an upper burn-in board and the cover 202 of a socket 200 mounted on a lower burn-in board may collide and/or be damaged. In addition, narrow spacing between vertically adjacent burn-in boards may hinder air flow, which may cause problems.

FIGS. 4 and 5 are sectional views for explaining the operation of a conventional latch 204 in socket 200. For example, in FIG. 4, a semiconductor package 40 may be loaded into the socket 200. In FIG. 5, the semiconductor package 40 may be mounted on the socket 200 and fixed by the latch 204. Because an external connection terminal may be a land in a LGA package, a socket pin 210 may not spontaneously contact an external connection terminal. In this case, the socket pin 210 may be connected to the land by a pressing force of a latch 204 disposed within the socket 200.

When the size of a LGA package increases, the length of the latch 204 may need to increase to guarantee the connection. As a result, the height of the cover 202 may increase. However, as described above, because the cover 202 of the socket 200 may be damaged due to the narrow spacing between vertically adjacent burn-in boards inserted into a rack, it may be difficult to lengthen the latch 204.

### SUMMARY OF THE INVENTION

An example embodiment of the present invention provides a test kit for a semiconductor package. The test kit may include a pick-and-place tool configured to load and/or unload a semiconductor package, a head assembly configured to guide a semiconductor package released from the pick-and-place tool, and a socket configured to receive the semiconductor package from the pick-and-place tool.

Another example embodiment of the present invention provides a method of testing a semiconductor package. The method may include aligning a head assembly with a socket by inserting at least one slide post of an alignment tool into a socket, releasing a semiconductor package through a package guider, and attaching the semiconductor package onto a socket.

Another example embodiment of the present invention provides a head assembly. The head assembly may include a package guider that surrounds a pick-and-place tool operation space and is configured to guide a semiconductor package onto a socket, and an alignment tool configured to align the head assembly with the socket.

Another example embodiment of the present invention provides a socket. The socket may include a latch driver configured to receive pressure applied by a latch press of an alignment tool, and a slide driver configured to receive a protrusion from an alignment tool.

An example embodiment of the present invention provides a socket where a latch driver and/or slide driver are exposed.

In an example embodiment of the present invention, the height of a socket may be reduced by 20-50% as compared with conventional sockets that include a socket cover.

An example embodiment of the present invention may facilitate parallel tests of semiconductor packages and may reduce costs for development and fabrication of sockets.

### BRIEF DESCRIPTION OF THE DRAWINGS

The present invention will become more apparent by describing in detail example embodiments thereof with reference to the attached drawings in which:

FIG. 1 is a sectional view of a conventional burn-in board mounted with a socket;

FIG. 2 is a top view of a conventional socket;

FIG. 3 is a side view of the conventional socket;

FIGS. 4 and 5 are sectional views for explaining the operation of a latch in the conventional socket;

FIG. 6 is a side view of a socket according to an example embodiment of the present invention;

FIG. 7 is a top view of the socket shown in FIG. 6 according to an example embodiment of the present invention;

FIG. 8 a perspective view of a head assembly according to an example embodiment of the present invention;

FIG. 9 is a top view of the head assembly shown in FIG. 8 according to an example embodiment of the present invention;

FIG. 10 is a front view of the head assembly shown in FIG. 8 according to an example embodiment of the present invention;

FIG. 11 is a perspective view of a unit head assembly shown in FIG. 8 according to an example embodiment of the present invention;

FIG. 12 is a top view of an alignment tool installed on a head assembly shown in FIG. 8 according to an example embodiment of the present invention;

FIG. 13 is a perspective view of the alignment tool shown in FIG. 12 according to an example embodiment of the present invention;

FIGS. 14A and 14B illustrate sides of the alignment tool of FIG. 12, viewed from the direction A and C, respectively, according to an example embodiment of the present invention;

FIG. 15 is a bottom view of the alignment tool installed to the head assembly shown in FIG. 8 according to an example embodiment of the present invention;

FIG. 16 is a perspective view of the alignment tool shown in FIG. 15 according to an example embodiment of the present invention; and

FIG. 17 is a sectional view illustrating a state in which semiconductor packages may be released and guided by a package guider of the head assembly shown in FIG. 8 according to an example embodiment of the present invention.

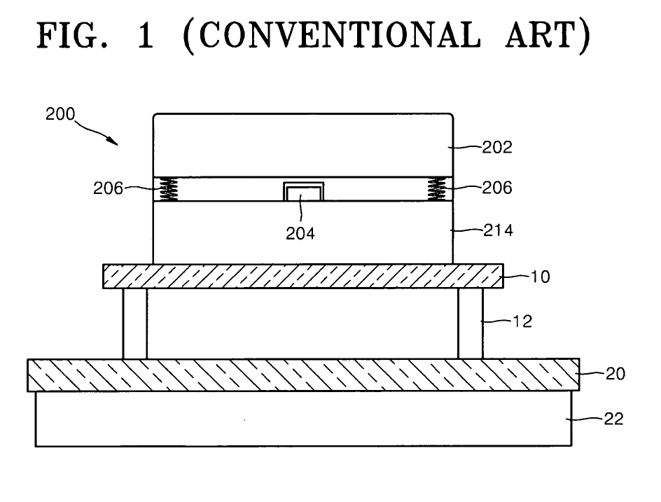

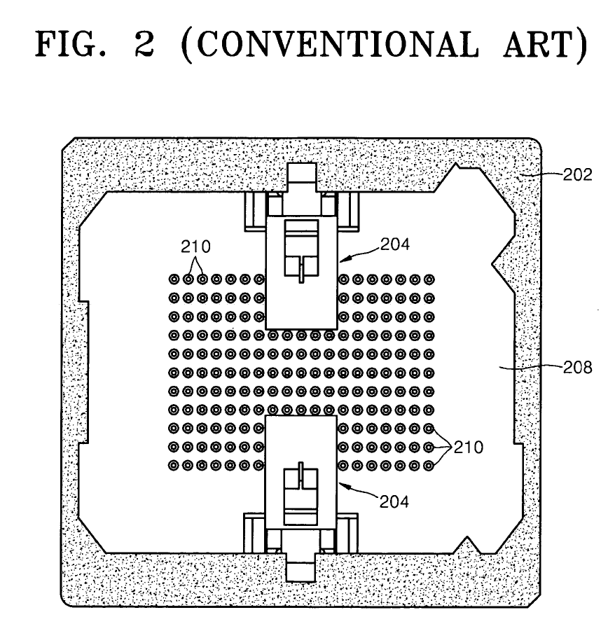

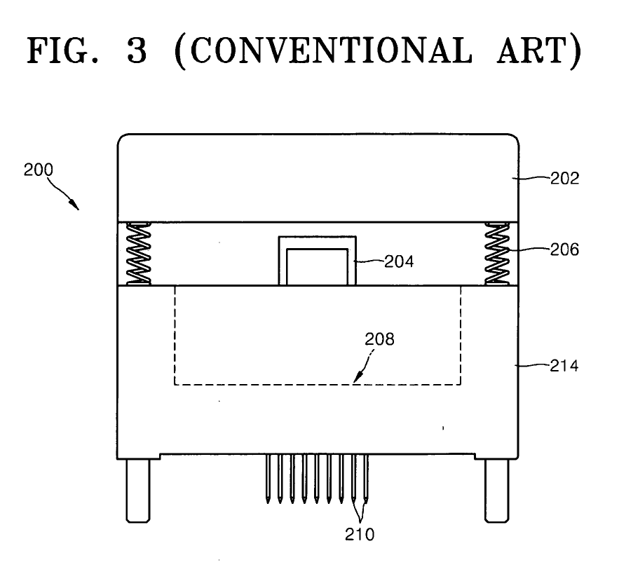

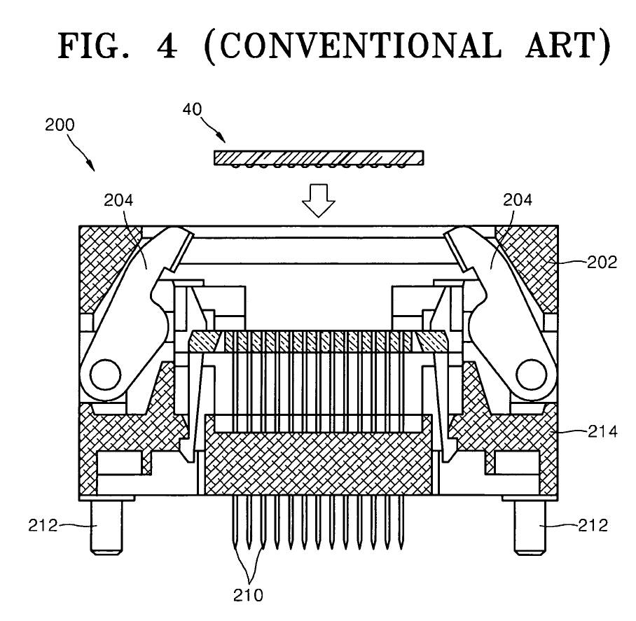

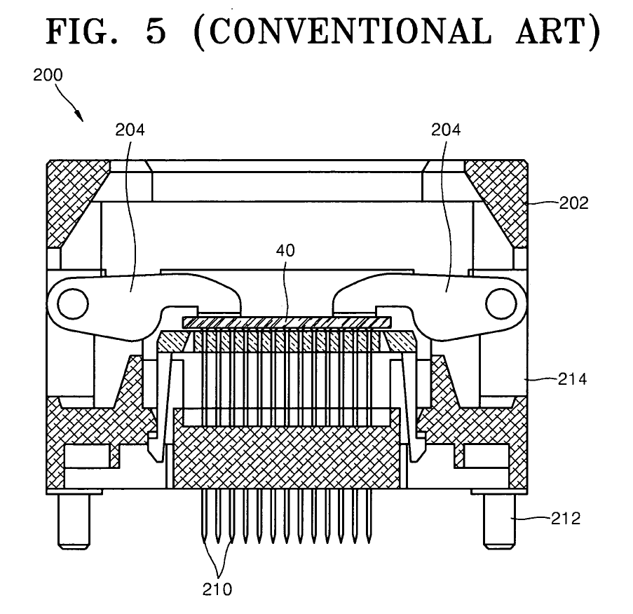

### DETAILED DESCRIPTION OF EXAMPLE EMBODIMENTS OF THE INVENTION

The present invention will now be described more fully with reference to the accompanying drawings, in which example embodiments of the invention are shown. The invention may, however, be embodied in many different forms and should not be construed as being limited to the example embodiments set forth herein; rather, these example embodiments are provided so that this disclosure will be thorough and complete, and will fully convey the concept of the invention to those skilled in the art. Like reference numerals in the drawings denote like elements.

Example illustrative embodiments of the present invention are disclosed herein. However, specific structural and functional details disclosed herein are merely representative for purposes of describing example embodiments of the present invention. This invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the present invention.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

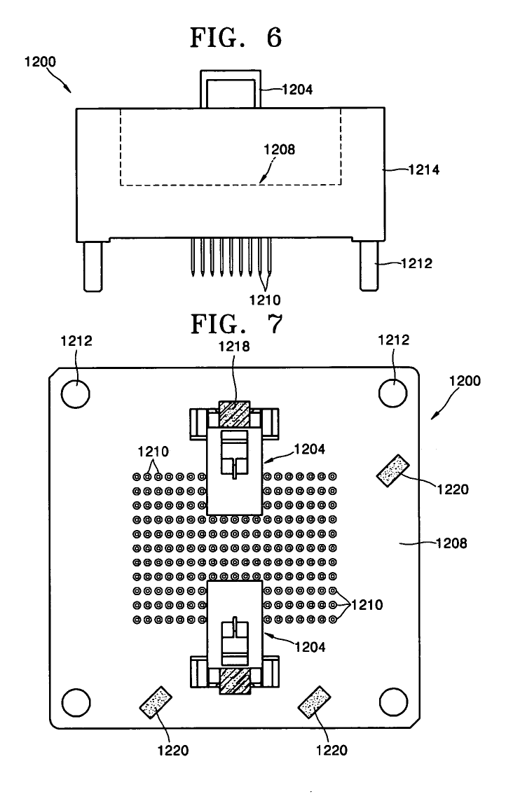

FIG. 6 is a side view of a socket 1200 according to an example embodiment of the present invention. FIG. 7 is a top view of the socket 1200 shown in FIG. 6.

Referring to FIGS. 6 and 7, the socket 1200 does not have a cover connected to a socket body 1214. A socket 1200 may include a latch 1204, a socket contact board 1208, a support portion 1212, socket pins 1210, a latch driver 1218, and/or a slide driver 1220. According to an example embodiment of the present invention, a latch driver 1218 and/or a slide driver 1220 may be exposed.

According to an example embodiment of the present invention, one or more latch drivers 1218 may open one or more latches 1204 in response to applied pressure. According to an example embodiment of the present invention, one or more slide drivers 1220 may open and/or close one or more socket pins 1210 in response to applied pressure so that the socket pins 1210 may be connected to external connection terminals (e.g., solder balls, solder lands, etc.) of a semiconductor package.

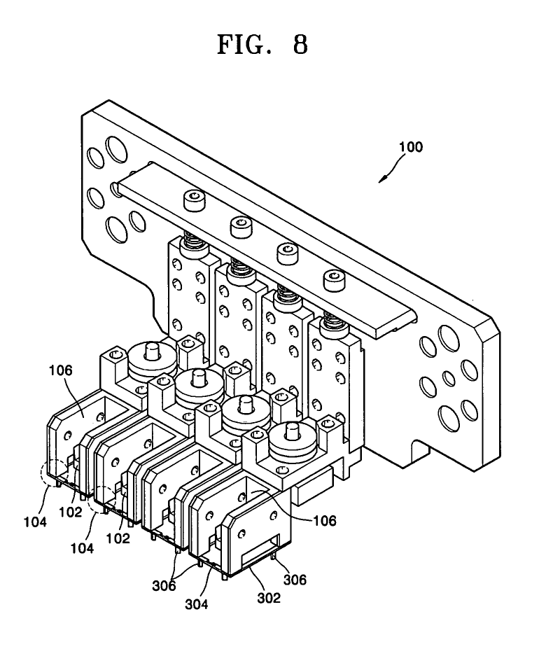

According to an example embodiment of the present invention, one or more protrusions of an alignment tool (300 shown in FIG. 13) arranged on a head assembly (100 shown in FIG. 8) may apply pressure to one or more of the latch drivers 1218 and/or one or more of the slide drivers 1220. For example, one or more latch drivers 1218 may be positioned to correspond with one or more latch presses (304 shown in FIG. 13), and one or more slide drivers 1220 may be positioned to correspond with one or more slide posts (306). Although the number of latch drivers 1218 corresponds to the number of latch presses 304 and the number of slide drivers 1220 corresponds to the number of slide posts 306 in the example embodiments illustrated in FIGS. 7 and 13, it should be noted that this is not meant to limit the present invention. For example, one latch press may be configured to apply pressure to more than one latch driver.

According to an example embodiment of the present invention, the socket 1200 may be mounted on a burn-in board in a monitoring burn-in test (MBT) and/or a parallel interface board in a final test of a semiconductor package. The socket 1200 may also be used and/or modified for other test and/or uses. According to an example embodiment of the present invention, when a socket 1200 is mounted on a burn-in board in a MBT, because socket 1200 does not have a cover, a problem of damaging the socket 1200 due to a narrow space between vertically adjacent burn-in boards inserted into slots of a rack in a land grid array (LGA) package may be reduced and/or prevented. Accordingly, a socket 1200 according to an example embodiment of the present invention may facilitate a MBT.

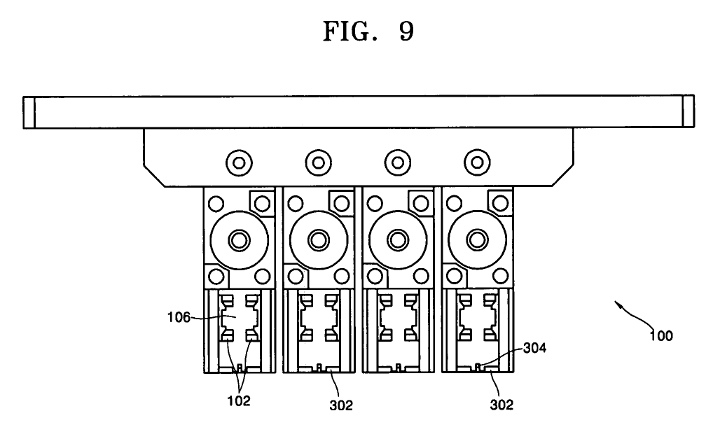

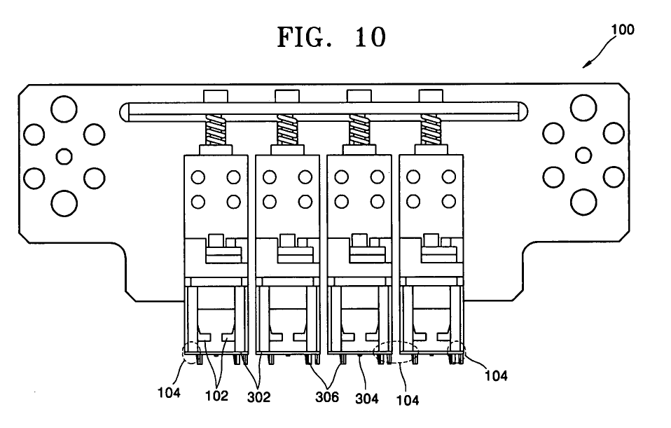

FIG. 8 is a perspective view of a head assembly 100 according to an example embodiment of the present invention. FIG. 9 is a top view of the head assembly 100 shown in FIG. 8. FIG. 10 is a front view of the head assembly 100 shown in FIG. 8.

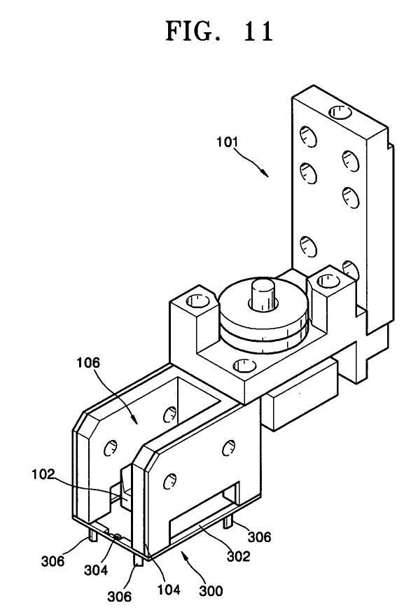

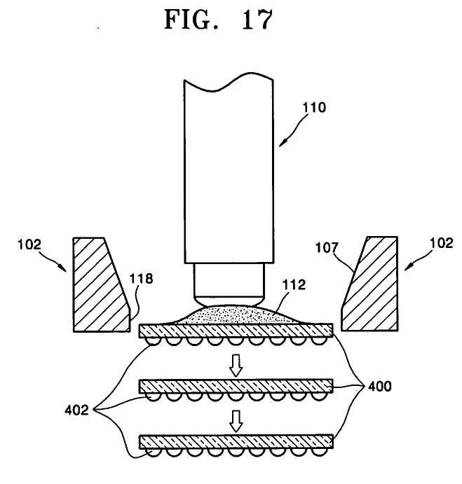

According to an example embodiment of the present invention, a head assembly 100 may be provided that may be suitable for substantially simultaneous loading and/or unloading of a plurality of semiconductor packages. A head assembly 100 may include a pick-and-place tool operating space 106 in which a pick-and-place tool (110 shown in FIG. 17), which may be used to load and/or unload a semiconductor package, may operate. A head assembly 100 may include a plurality of unit head assemblies (101 shown in FIG. 11). For example, a head assembly 100 may include four unit head assemblies. Each unit head assembly 101 may have a package guider 102 and/or a socket guider 104. The package guider 102 may guide a semiconductor package when, for example, the pick-and-place tool 110 releases a semiconductor package so that the semiconductor package may be connected to socket pins 1210. An example embodiment of aligning and releasing of the present invention is described later with reference to FIG. 17.

A head assembly 100 according to an example embodiment of the present invention may include an alignment tool 300 (FIG. 13). An alignment tool 300 may be installed under a socket guider 104 and may perform one or more functions. For example, an alignment tool 300 may function to apply pressure to a latch, align a head assembly with a socket, etc. An alignment tool 300 may be positioned at a lower portion of a head assembly 100, may have one or more slide posts 306 and/or one or more latch presses 304.

FIG. 11 is a perspective view of a unit head assembly 101 according to an example embodiment of the present invention as shown in FIG. 8. Referring to FIG. 11, an alignment tool 300 may be attached to the bottom of a socket guider 104 of a unit head assembly 101. Slide posts 306 of an alignment tool 300 may be inserted into slide drivers 1220 (FIG. 7) of a socket 1200 (FIG. 7) when the unit head assembly 101 moves towards a socket 1200 to load a semiconductor package. Accordingly, alignment may be performed using an alignment tool 300. The latch presses 304 may press the latch drivers 1218 (FIG. 7) of the socket 1200.

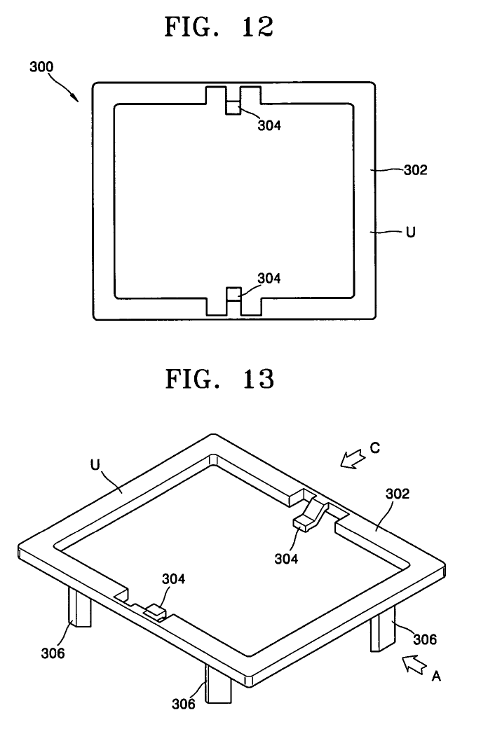

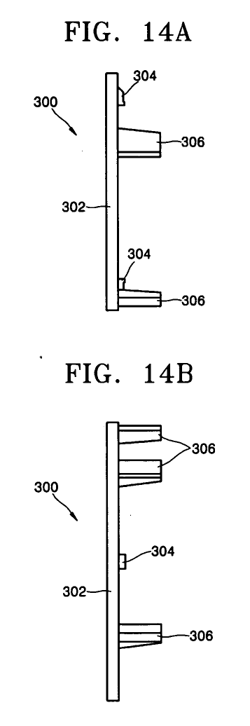

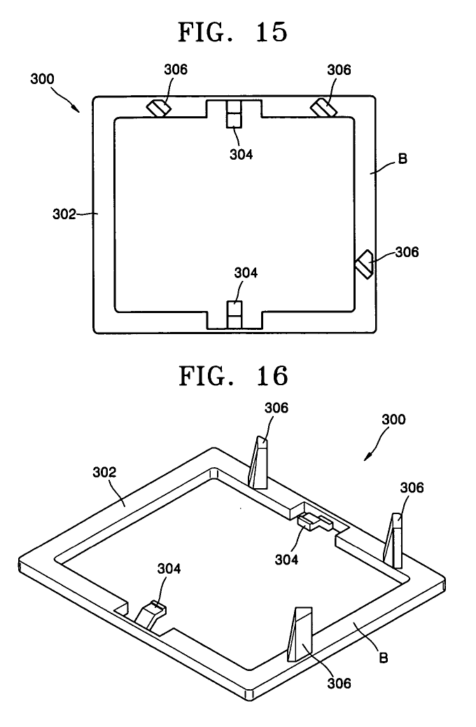

FIG. 12 is a top view of an alignment tool 300 installed on a head assembly 100 according to an example embodiment of the present invention as shown in FIG. 8. FIG. 13 is a perspective view of an alignment tool 300 according to an example embodiment of the present invention as shown in FIG. 12. FIGS. 14A and 14B illustrate sides of an alignment tool 300 according to an example embodiment of the present invention as shown in FIG. 12, viewed from the direction A and C, respectively. FIG. 15 is a bottom view of an alignment tool 300 installed on the head assembly 100 according to an example embodiment of the present invention as shown in FIG. 8. FIG. 16 is a perspective view of an alignment tool 300 according to an example embodiment of the present invention as shown in FIG. 15.

According to an example embodiment of the present invention as illustrated in FIGS. 12 through 15, an alignment tool 300 may have a top surface U (FIG. 12) which may be attached to a bottom of a socket guider 104 (FIG. 11) of a unit head assembly 101 (FIG. 11). The alignment tool 300 may also have a bottom surface B (FIG. 15) exposed and/or contacting a socket 1200.

According to an example embodiment of the present invention, an alignment tool 300 may include an alignment tool body 302, one or more latch presses 304 and/or one or more latch drivers 1218. For example, one or more latch presses 304 may be arranged on a bottom surface of an alignment tool body 302 and may be configured to press the one or more latch drivers 1218 (FIG. 7) of the socket 1200. One or more slide posts 306 may be arranged on a bottom surface B of the alignment tool body 302 and may be configured to press one or more slide drivers 1220 (FIG. 7) of the socket 1200. Applying pressure to the one or more slide drivers 1220 may open and/or close one or more socket pins 1210 (FIG. 7). The positions and/or shapes of elements included in the alignment tool 300 may be changed and/or modified without departing from the fundamental spirit of the present invention.

FIG. 17 is a sectional view illustrating a state in which semiconductor packages may be released and guided by a package guider 102 of the head assembly 100 according to an example embodiment of the present invention. Referring to FIG. 17, a pick-and-place tool 110 may include a vacuum suction unit 112 to attract and/or move a semiconductor package 400 using the vacuum suction unit 112. For example, a pick-and-place tool 110 may attract a semiconductor package 400, may move the pick-and-place tool 110 with an attached semiconductor package 400 to a pick-and-place tool operating space 106 (FIG. 11), and may release the semiconductor package 400 from the pick-and-place tool 110 to place the semiconductor package 400 on a socket contact board 1208 (FIG. 7) of the socket 1200 (FIG. 7). According to an example embodiment of the present invention, a package guider 102 may have an inclined portion 107. The inclined portion 107 may function to guide the semiconductor package 400 released by the pick-and-place tool 110. For example, the semiconductor package 400 sliding along the inclined portion 107 may be correctly placed and/or oriented on the socket contact board 1208 so that solder balls 402 of the semiconductor package 400 are connected to the socket pins 1210 (FIG. 7) of the socket 1200.

While the present invention has been particularly shown and described with reference to example embodiments thereof, it will be understood by those of ordinary skill in the art that various changes in form and details may be made therein without departing from the spirit and scope of the present invention.

What is claimed is:

1. A test kit for a semiconductor package, comprising:
a pick-and-place tool configured to load/unload the semiconductor package;
a head assembly configured to guide the semiconductor package released from the pick-and-place tool; and
a socket configured to receive the semiconductor package from the pick-and-place tool.

2. The test kit of claim 1, wherein the socket does not have a cover.

3. The test kit of claim 1, wherein the head assembly is further configured to align the head assembly with the socket.

4. The test kit of claim 1, wherein the head assembly includes a package guider that surrounds a pick-and-place tool operating space and guides the semiconductor package released from the pick-and-place tool.

5. The test kit of claim 1, wherein the head assembly includes an alignment tool aligning the head assembly with the socket.

6. The test kit of claim 5, wherein the alignment tool comprises:
an alignment tool body having a rectangular shape;
at least one latch press arranged on a bottom surface of the alignment tool body to press at least one latch driver of the socket; and
at least one slide post arranged on a bottom surface of the alignment tool body to press at least one slide driver of the socket.

7. The test kit of claim 6, wherein the at least one latch press and the at least one slide post protrude from the bottom surface of the alignment tool.

8. The test kit of claim 1, wherein the socket is mounted on an interface board used for a burn-in test.

9. The test kit of claim 8, wherein the burn-in test is a monitoring burn-in test (MBT).

10. The test kit of claim 1, wherein the socket is mounted on an interface board used for a parallel test of the semiconductor package.

11. The test kit of claim 1, wherein the socket is used for a land grid array (LGA) package.

12. The test kit of claim 1, wherein the pick-and-place tool attracts and loads/unloads the semiconductor package using a vacuum.

13. The test kit of claim 5, wherein the head assembly further comprises a socket guider having a structure allowing the alignment tool to be attached to a bottom of the socket guider.

14. A method of testing a semiconductor package, comprising:
aligning a head assembly with a socket by inserting at least one slide post of an alignment tool into a socket;
releasing a semiconductor package through a package guider; and
attaching the semiconductor package onto a socket.

15. The method of claim 14, wherein the aligning inserts the at least one slide post into at least one slide driver of the socket.

16. The method of claim 14, further comprising:
attracting the semiconductor package using a pick-and-place tool; and
moving the pick-and-place tool to a location above the package guider.

17. The method of claim 14, wherein the attaching includes pressing at least one latch driver of the socket using at least one latch press arranged on the alignment tool.

18. The method of claim 14, further comprising:
preparing an interface board mounted with a plurality of sockets that do not have covers.

19. The method of claim 14, wherein the attaching includes pressing an upper portion of the semiconductor package using a latch arranged on the socket.

20. The method of claim 14, further comprising:
performing an electrical test on the semiconductor package attached to the socket.

21. A head assembly comprising:
a package guider that surrounds a pick-and-place tool operating space and is configured to guide a semiconductor package onto a socket; and
an alignment tool configured to align the head assembly with the socket.

22. A socket comprising:
a latch driver configured to receive pressure applied by a latch press; and
a slide driver configured to receive a protrusion from an alignment tool.

23. An alignment tool comprising:
an alignment tool body;
at least one latch press arranged on a bottom surface of the alignment tool body to press at least one latch driver of the socket; and
at least one slide post arranged on a bottom surface of the alignment tool body to press at least one slide driver of the socket.
